(19) United States
(12) Patent Application Publication
(10) Pub. No.: US 2014/0021938 A1
(43) Pub. Date: Jan. 23, 2014

(54) MULTI-CHANNEL PWM WAVEFORM MEASURING DEVICE

(71) Applicant: Sangyong Lee, Gyeonggi-do (KR)

(72) Inventor: Sangyong Lee, Gyeonggi-do (KR)

(21) Appl. No.: 14/009,779

(22) PCT Filed: Mar. 20, 2012
(86) PCT No.: PCT/KR12/01978

§ 371 Date: Oct. 3, 2013

(30) Foreign Application Priority Data
Apr. 6, 2011 (KR) 10-2011-0031608

(51) Int. Cl. G01R 29/02

(52) U.S. Cl. CPC G01R 29/023
USPC 324/76.12

(57) ABSTRACT

The present invention relates to a multi-channel PWM waveform measuring device, and more particularly, to a multi-channel PWM waveform measuring device which maximally prevents the loss of an expensive power semiconductor device during the diagnostic process of a complex servo drive and reduces damage of the PCB of the servo drive in order to restore the servo drive safely and quickly. In a multi-channel PWM waveform measuring device for checking a PWM output state of a main control PCB of a servo drive, provided are: a measurement jig outputting a measurement signal to a communication cable through a plurality of probes, which are pre-installed corresponding to each of the measurement points of an inverter and converter for measuring PWM waveforms, wherein the main control PCB of a detachable servo drive, i.e. a checking target, is connected to the base terminal of a transistor equipped in the pre-installed inverter and converter through a connector; a signal processing unit collecting measurement signals through the communication cable and outputting a measurement signal of a probe connected to a switch which is in an on-state through a manipulation button; and a signal outputting unit outputting a PWM waveform on a screen, wherein a measurement signal inputted from the signal processing unit represents a change of an input voltage with respect to time.

### CROSS-REFERENCE TO RELATED APPLICATION

This application claims the benefit of Korean Patent Application No.10-2011-0031608, filed on Apr. 6, 2011 in the Korean Intellectual Property Office, the disclosure of which is incorporated herein by reference.

### TECHNICAL FIELD

The present invention relates to a multi-channel Pulse Width Modulation (PWM) waveform measuring device, and more particularly, to a multi-channel PWM waveform measuring device, which can safely and quickly restore a servo drive by maximally reducing a loss of an expensive power semiconductor device and a damage of a servo drive PCB during a complex diagnosis process of the servo drive.

### BACKGROUND ART

Generally, the diagnosis of a servo unit is performed through waveform measurement using an oscilloscope based on a check point of a main control printed circuit board (PCB).

However, the measurement using the oscilloscope is complicated and difficult for a person who is not a specialist in the corresponding equipment. In case of servo drive, since there are many measurement points, much time and skill are needed to find a defective component using direct waveform measurement on a PCB.

Recently, an oscilloscope and a comparator that are waveform measurement devices, an analog and digital testers, and an LCR measurement instrument are being used for the maintenance of a servo, but there is a limitation in diagnosing and repairing a defective part of a servo amp.

In case of servo unit, a high technological experience and skill are needed for the maintenance of the servo unit (need to know all measurement points of a transistor (TR) of a spindle drive, and TR may burst due to a wrong checkpoint), and a user has to know the theory of the control characteristics of the servo. Particularly, since a converter part and an inverter part have many parts in which a small current is amplified to a high current, a mistake may lead to a negligent accident, making it difficult to deal with the converter part and the inverter part.

### DISCLOSURE

### Technical Problem

The present invention provides a multi-channel PWM waveform measuring device, which can safely and quickly restore a servo drive by maximally reducing a loss of an expensive power semiconductor device and a damage of a servo drive PCB during a complex diagnosis process of the servo drive.

The present invention also provides a multi-channel PWM waveform measuring device, which allows a user to inspect the state and damage of different servo drives by each manufacturer.

The present invention also provides a multi-channel PWM waveform measuring device, which can remove a failure cause of a servo drive by analyzing a waveform and finding an abnormal waveform by reversely tracing (from a final output terminal of a gate driver to a PCB) inverter and converter driving parts of a circuit that generate different waveforms using the measuring device.

The present invention also provides a multi-channel PWM waveform measuring device, which can allow a user to easily check the state of a drive.

The objects of the present invention are not limited to the above. Other objects will be clearly understood by the persons skilled in the art from the following description.

### Technical Solution

In accordance with an aspect of the present invention, there is a multi-channel Pulse Width Modulation (PWM) waveform measuring device for checking a PWM output state of a main control PCB of a servo drive, the device comprising: an inverter and a converter; a connector equipped with a Printed Circuit Board (PCB) of a detachable servo drive and connecting the inverter and the converter to the PCB; a plurality of probes measuring a PWM waveform and installed at a predetermined measurement point in the inverter and the converter; a measurement jig outputting a signal measured by the plurality of probes to a communication cable; a signal processor collecting measurement signals through the communication cable of the measurement jig and outputting a measurement signal of a probe connected to a switch which is in on-state by an operation button; and a signal output unit displaying the measurement signal inputted from the signal processor as a PWM waveform on a screen.

Preferably, the signal processor may include a pin connector connected to the communication cable to collect the measurement signal outputted from the probe.

Preferably, the signal output unit may include: a personal computer; and an oscilloscope connected to the personal computer to receive a control command from the personal computer and displaying the inputted measurement signal as the PWM waveform for checking the state of the PCB of the servo drive.

Preferably, the oscilloscope may be one of an analog oscilloscope, a digital oscilloscope, and a Universal Serial Bus (USB) oscilloscope.

Preferably, the signal processor may include: a multiplexer selectively outputting one of the measurement signals collected by the operation button; and a switch unit comprising switches corresponding one-to-one to the plurality of probes and outputting a measurement signal correspondently connected to an on-state switch among the measurement signals collected by the plurality of probes when switched on by the multiplexer.

Preferably, the switch unit may include a plurality of relays.

Preferably, the measurement jig may be variously manufactured in consideration of the measurement points according to the location of the inverter and the converter of different servo drive manufacturers that are different from each other in the location and the number of transistors provided in the inverter and the converter.

Preferably, the number of probes may correspond to the number of transistors constituting the inverter and the converter.

### Advantageous Effects

A multi-channel PWM waveform measuring device according to an embodiment of the present invention has an effect of safely and quickly restoring a servo drive by maximally reducing a loss of an expensive power semiconductor device and a damage of a servo drive PCB during a complex diagnosis process of the servo drive.

Also, the present invention has an effect of checking the state and damage of servo drive PCBs from different manufacturers.

Furthermore, the present invention has an effect of removing an abnormality cause of the servo drive by analyzing waveforms to find an abnormal waveform by reversely tracing inverter and converter driving parts of a circuit generating each waveform using the measuring device.

In addition, the present invention can allow a user to easily check the state of a drive.

### BRIEF DESCRIPTION OF DRAWINGS

FIG. 1 is a view illustrating a typical closed loop system.

FIG. 2 is a view illustrating a multi-channel PWM waveform measuring device according to an embodiment of the present invention.

FIG. 3 is a view illustrating an inverter and a converter provided in a measurement jig in FIG. 2.

FIG. 4 a, FIG. 4 b and FIG. 4 c are a view illustrating an inverter and a converter destroyed by an abnormality.

FIGS. 5A and 5B are views illustrating a signal processor in FIG. 2.

FIG. 6 is a view illustrating waveforms measured by a multi-channel PWM waveform measuring device according to an embodiment of the present invention.

### BEST MODES FOR CARRYING OUT THE INVENTION

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

Hereinafter, exemplary embodiments of the present invention will be described in detail with reference to the accompanying drawings.

A multi-channel Pulse Width Modulation (PWM) waveform measuring device according to an embodiment of the present invention can check five causes of a transistor (TR) module damage of a spindle drive: 1. drive sequence switching failure; 2. abnormal operation of gate drive circuit of converter base board; 3. interface contact failure with main control PCB; 4. overcurrent; and 5. failure of main control Printed Circuit Board (PCB).

Hereinafter, exemplary embodiments of the present invention will be described in detail with reference to the accompanying drawings, but the description will be focused on parts necessary for understanding of the operation and action of the present invention.

In the following description, a measurement signal denotes a signal measured by a probe preset according to measurement points of an inverter and a converter to check the state of a main control PCB of a servo drive by measuring a PWM waveform, and may mean a measurement signal that allows a user to check whether or not an element located in any column or row in the main control PCB of the servo drive is defective according to the measurement signals outputted corresponding to the column or row of each element of the servo drive.

In the following description, the specific details of the multi-channel PWM waveform measuring device will be provided for further overall understanding of the present invention, and it will be understood by those skilled in the art that the present invention can be easily carried out without these specific details or by modifications thereof.

The features of a multi-channel PWM waveform measuring device according to an embodiment of the present invention will be described as follows.

First, the multi-channel PWM waveform measuring device may measure a PWM drive waveform that is difficult for an oscilloscope to analyze, and may analyze and diagnose the switching sequence of an inverter drive.

Second, the multi-channel PWM waveform measuring device may prevent damage of expensive switching module parts through diagnosis and inspection of a main control PCB before the combination of a servo unit.

Third, main control PCBs of various servo drives can be simply diagnosed in a short time by systematizing the PWM measurement.

A comparison between the measurement methods using the multi-channel PWM waveform measuring device and the oscilloscope is described in Table 1 below.

TABLE 1

| | | Number | | |
|---|---|---|---|---|
| | | of | | |
| Measurement | Measurement | measured | Work | |
| method | time | channels | difficulty | Safety |
| Oscilloscope | 30 mins to | Limited | a little | a little |
| | 2 hrs | (2 or 4 | difficult | dangerous |
| | | channel | | due to |
| | | set when | | manual |
| | | shipped) | | measurement |
| | | | | of a high |
| | | | | voltage |
| | | | | part after |
| | | | | the power |
| | | | | is applied |
| Multi- | within 10 | 1 to N | Simple | Very safe |
| channel PWM | mins | (N is a | and easy | due to use |
| waveform | | possible | | of a |
| measuring | | number | | measurement |
| device | | to set) | | jig |

That is, in the multi-channel PWM waveform measuring device, the measurement time may be within about 10 minutes, and the number of measured channels may correspond to the number of transistors constituting the inverter and the converter. Thus, the PWM waveforms of the inverter and the converter can be easily measured, and the measurement jig may enable the safe measurement. Compared to the measurement using a typical oscilloscope, the measurement time may be shortened, and the number of measured channels may differ from that of a typical oscilloscope that can measure only a predetermined number of channels when shipped. Also, the multi-channel PWM waveform measuring device may differ from a typical oscilloscope in that the measurement of the PWM waveform using the multi-channel PWM waveform measuring device is very safe and simple compared to those of a typical oscilloscope that is dangerous due to the manual measurement on high voltage parts after power is applied.

The main control PCB, which performs control actions, may include a signal generating unit that generates a PWM signal to drive a servo spindle motor, a signal driving unit, and an automatic controller that detects an output signal from a sensor to feed back the output signal.

The control action may mean that in the driving of the spindle motor, the automatic controller compares a desired value that is a reference input with an actual value that is outputted from a plant to calculate an error value and a control signal is generated such that the calculated error value becomes zero or a very small value to form an optimal number of revolution that is desired by a user. This process of generating the control signal by the automatic controller may be defined as “control action”.

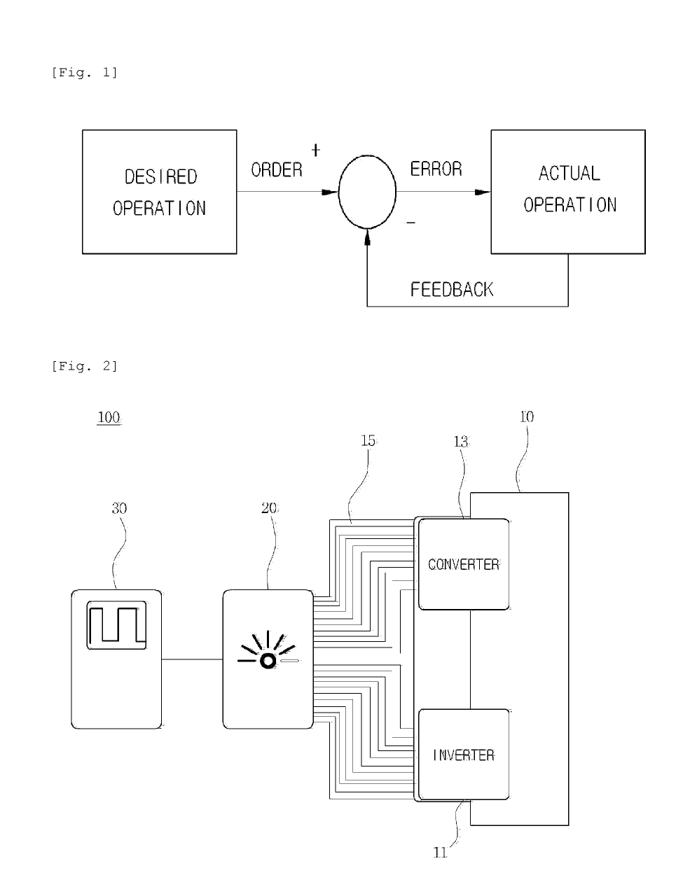

A typical servo instrument may be a closed loop system as shown in FIG. 1, which performs control with three components including orders, feedback signals, and errors. Here, the order may denote a target value, and the feedback may denote actual data. Also, the error may denote a difference between the target value and the actual value.

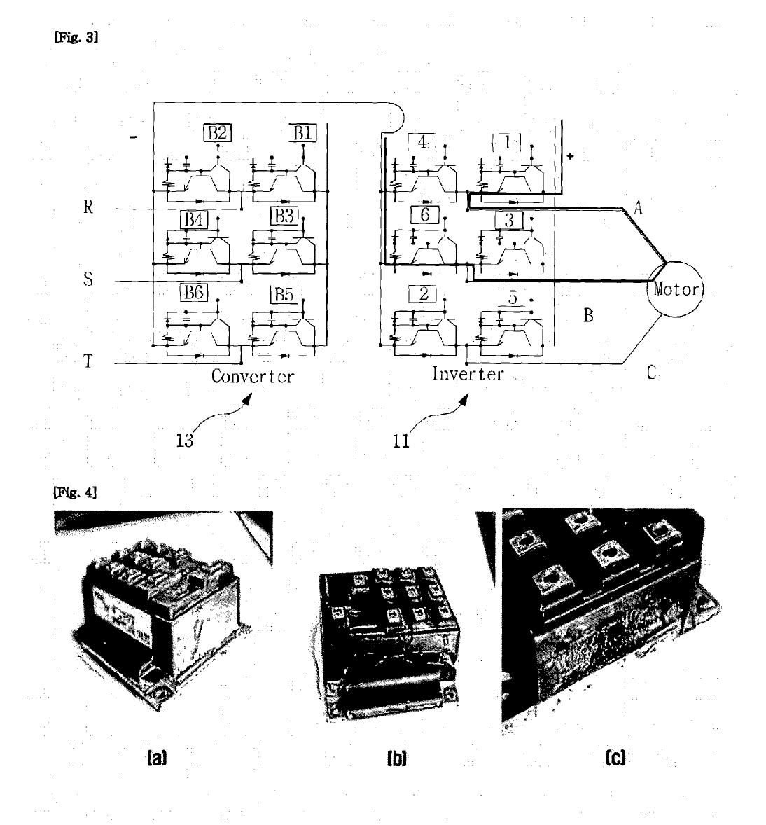

FIG. 2 is a view illustrating a multi-channel PWM waveform measuring device according to an embodiment of the present invention.

Referring to FIG. 2, a multi-channel PWM waveform measuring device 100 according to an embodiment of the present invention may be configured to include a measurement jig 10, a signal processor 20, and a signal output unit 30.

The measurement jig 10 may be configured such that the main control PCB of a detachable servo drive of a target to check is connected to an inverter 11 and a converter 13 through connectors provided on an upper portion of the measurement jig 10. Thereafter, the measurement jig 10 may acquire measurement signals through a plurality of probes 15 that are pre-installed corresponding to measurement points of the inverter 11 and the converter 13 for the measurement of the PWM waveforms, and then outputs the acquired measurement signals to the signal processor 20 connected via a communication cable. Here, the number of probes 15 may correspond to the number of transistors constituting the inverter 11 and the converter 13.

The measurement jig 10 may use a finished product of the servo drive, and may be manufactured by connecting the plurality of probes to a plurality of measurement points for the measurement of the PWM waveforms of the inverter 11 and the converter 13. In this case, the measurement jig 10 may be variously manufactured in consideration of the measurement points according to the location of the inverter and the converter of different servo drive manufacturers that are different from each other in the location and the number of the inverter 11 and the converter 13, and the location of base terminals of transistors (TR) provided in the inverter 11 and the converter 13. Here, the configuration and the circuit structure of the inverter 11 and the converter 13 will be described later.

The signal processor 20 may collect measurement signals through a communication cable (not shown), and may output a measurement signal of a probe connected to a switch that is in on-state by an operation button. The signal processor 20 may include a multiplexer (not shown) that selectively outputs one of measurement signals collected by the operation of the button and a switch unit (not shown) that includes switches corresponding one-to-one to the plurality of probes and is switched on by the multiplexer to output measurement signals correspondently connected to the on-state switches among the measurement signals collected from the plurality of probes 15. Here, the switch unit may include a plurality of relays. The signal processor 20 may include a pin connector (not shown) connected to the communication cable to collect the measurement signals outputted from the probes 15.

The configuration of the signal processor 20 will be described in detail later.

The signal output unit 30 may output measurement signals inputted from the signal processor 20 on a screen in a form of PWM waveform. In this case, the PWM waveform may be displayed as a variation of an input voltage according to time.

Here, the signal output unit 30 may include a personal computer and an oscilloscope that is connected to the personal computer to display measurement signals inputted through a control command of the personal computer in a form of PWM waveform for checking the state of the main control PCB of the servo drive.

Here, the oscilloscope may be one of analog-typed oscilloscope, digital-typed oscilloscope, and a USB oscilloscope.

### Modes for Carrying Out the Invention

FIG. 3 is a view illustrating an inverter and a converter provided in a measurement jig in FIG. 2. The solid line of FIG. 3 at the side of the inverter 11 shows a loop in which TR 1 and TR 6 are turned on according to the sequence.

Referring to FIG. 3, the measurement jig 10 may include a converter 13 that rectifies AC three-phase power source (R, S, T) and then converts AC into DC and an inverter 11 that receives the DC voltage outputted from the converter 13 and converts the DC voltage into an AC voltage having a voltage and a frequency necessary for the driving of the motor by a PWM method.

Probes 15 may be preset in accordance with the number of measurement points so as to correspond one-to-one to base terminals (e.g., about 12 measurement points in FIG. 2) of TR that are measurement points of TR in accordance with the number of TRs of the inverter 11 and the converter 13 that perform the foregoing operation, respectively.

Accordingly, an inconvenience of knowing all measurement points of TR of a servo driver and a bursting phenomenon of TR like FIG. 3 due to a wrong measurement point can be prevented.

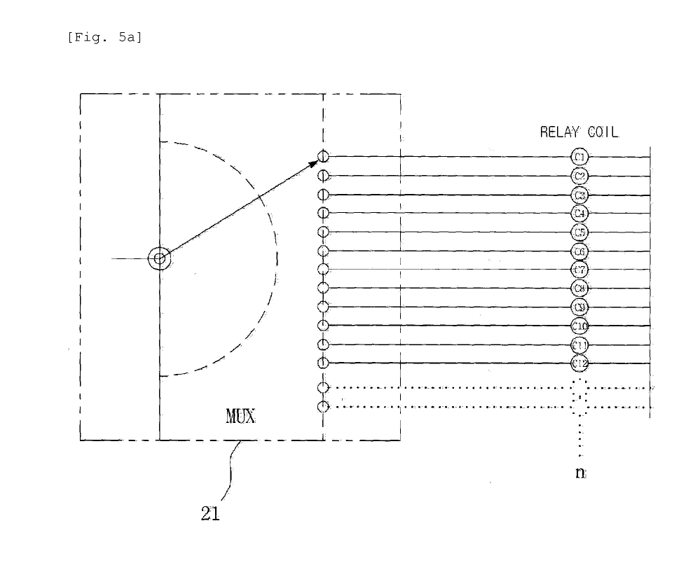

The bursting phenomenon of TR like FIG. 4 may also occur in the following case.

When a rotation order is delivered to the servo driver, a gate signal may be applied to six switches to form a rotating magnetic field in the spindle motor and then rotate the motor. By the way, when an abnormal waveform occurs among waveforms outputted through six TRs constituting the inverter 11 and the converter 13 that receive the six gate signals, the rotation may become irregular or may affect the torque, generating an overcurrent and thus destroying the TR module. In severe cases, the servo driver PCB may be seriously damaged.

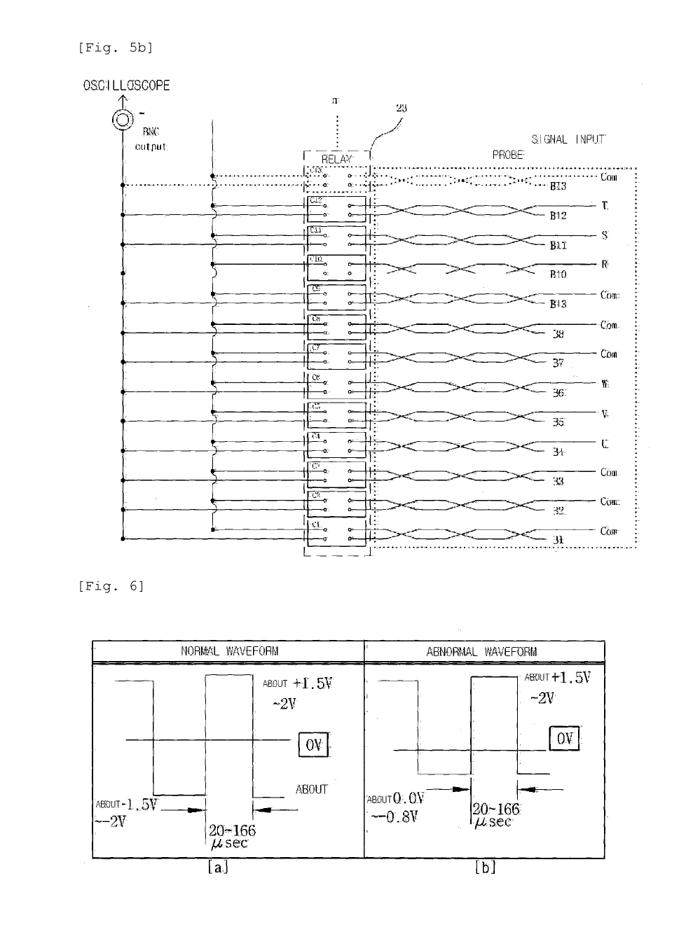

FIGS. 5A and 5B are views illustrating a signal processor in FIG. 2.

Referring to FIGS. 5A and 5B, the signal processor 20 may collect all measurement signals measured at the measurement points of the inverter 11 and the converter 13 through the probe 15 connected to the pin connector, and then may select one of the collected measurement signals through the multiplexer 21 according to the operation of the button.

Thereafter, the multiplexer 21 may allow a current to flow in one selected from a plurality of relay coils C1, C12, . . . , n.

Then, a relay (switch) of the switch unit 23 corresponding to the relay coil in which a current flows may be turned on (short-circuited), transmitting an oscilloscope measurement signal of the signal output unit 30.

Finally, the signal output unit 30 may receive the measurement signal to display the measured PWM waveform on a screen, and may allow a user to check whether or not there is an abnormality of the servo drive. In other words, the waveform may be analyzed to find an abnormal waveform by reversely tracing the failure cause of the servo drive through the measurement waveform.

FIG. 6 is a view illustrating waveforms measured by a multi-channel PWM waveform measuring device according to an embodiment of the present invention.

Referring to FIGS. 6, FIG. 6A shows a normal waveform, and FIG. 6B shows an abnormal waveform. The waveforms may be displayed through the signal output unit 30.

The normal waveform shows a pulse of about +1.5V to 2V switching voltage and about −1.5V to 2V voltage based on 0V.

On the other hand, in the abnormal waveform of FIG. 6B, the positive (+) voltage stably ranges from about 1.5V to about 2V, but the negative (−) voltage ranges about 0V to about 0.8V, making it difficult to switch. Accordingly, the abnormal waveform may be determined as a defective waveform.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

1. A multi-channel PWM waveform measuring device for checking a Pulse Width Modulation (PWM) output state of a main control PCB of a servo drive, the device comprising:
an inverter and a converter;
a connector equipped with a Printed Circuit Board (PCB) of a detachable servo drive and connecting the inverter and the converter to the PCB;
a plurality of probes measuring a PWM waveform and installed at a predetermined measurement point in the inverter and the converter;
a measurement jig outputting a signal measured by the plurality of probes to a communication cable;
a signal processor collecting measurement signals through the communication cable of the measurement jig and outputting a measurement signal of a probe connected to a switch which is in on-state by an operation button; and
a signal output unit displaying the measurement signal inputted from the signal processor as a PWM waveform on a screen.

2. The multi-channel PWM waveform measuring device of claim 1, wherein the signal processor comprises a pin connector connected to the communication cable to collect the measurement signal outputted from the probe.

3. The multi-channel PWM waveform measuring device of claim 1, wherein the signal output unit comprises:
a personal computer; and
an oscilloscope connected to the personal computer to receive a control command from the personal computer and displaying the inputted measurement signal as the PWM waveform for checking the state of the PCB of the servo drive.

4. The multi-channel PWM waveform measuring device of claim 3, wherein the oscilloscope is one of an analog oscilloscope, a digital oscilloscope, and a Universal Serial Bus (USB) oscilloscope.

5. The multi-channel PWM waveform measuring device of claim 1, wherein the signal processor comprises:
a multiplexer selectively outputting one of the measurement signals collected by the operation button; and
a switch unit comprising switches corresponding one-to-one to the plurality of probes and outputting a measurement signal correspondently connected to an on-state switch among the measurement signals collected by the plurality of probes when switched on by the multiplexer.

6. The multi-channel PWM waveform measuring device of claim 5, wherein the switch unit comprises a plurality of relays.

7. The multi-channel PWM waveform measuring device of claim 1, wherein the measurement jig is variously manufactured in consideration of the measurement points according to the location of the inverter and the converter of different servo drive manufacturers that are different from each other in the location and the number of transistors provided in the inverter and the converter.

8. The multi-channel PWM waveform measuring device of claim 1, wherein the number of probes corresponds to the number of transistors constituting the inverter and the converter.
